(19) United States
(12) Patent Application Publication
(10) Pub. No.: US 2001/0052626 A1
(43) Pub. Date: Dec. 20, 2001

(54) Method for fabricating dual-gate structure

(75) Inventor: Guo-Qiang Lo, Portland, OR (US)

Correspondence Address: INTEGRATED DEVICE TECHNOLOGY, ISABELLE R. MCANDREWS, 2975 STENDER WAY, M/S C4-25, SANTA CLARA, CA, 95054, US

(73) Assignee: Integrated Device Technology, Inc.

(21) Appl. No.: 09/938,349

(22) Filed: Aug. 23, 2001

Related U.S. Application Data
(62) Division of application No. 09/395,526, filed on Sep. 14, 1999.

(51) Int. Cl. H01L 29/76; H01L 29/94; H01L 31/062; H01L 31/113; H01L 31/119

(52) U.S. Cl. 257/412

(57) ABSTRACT

A dual-gate semiconductor structure including a first polysilicon layer that has a p-type region and an n-type region. The p-type region overlies the channel region of a p-channel transistor, and the n-type region overlies the channel region of an n-channel transistor. A second polysilicon layer is formed directly on the first polysilicon layer, and exhibits good adhesion with the first polysilicon layer. A metal silicide layer is deposited on the second polysilicon layer. The second polysilicon layer and the metal silicide layer are deposited in different chambers of the same equipment, without breaking vacuum (i.e., in situ). The upper surface of the second polysilicon layer is therefore relatively clean, thereby providing good adhesion between the metal silicide and second polysilicon layers. The second polysilicon layer, which is either undoped or doped with nitrogen, inhibits vertical migration of impurities in the first and second regions to the overlying metal silicide layer.

### BACKGROUND OF THE INVENTION

1. Field of the Invention

The present invention relates to a dual-gate semiconductor structure. More specifically, the present invention relates to a dual-gate structure that includes a polysilicon layer having both n-type and p-type regions, and an overlying layer of metal silicide.

2. Discussion of Related Art

FIG. 1 is a cross sectional view of a conventional semiconductor structure 100, which includes p-type substrate 101, n-well 102, p-type channel region 103, n-type channel region 104, field oxide 105, gate oxide 106, polysilicon layer 107 (which includes n+ polysilicon region 108 and p+ polysilicon region 109), and metal silicide layer 110. Polysilicon layer 107 and metal silicide layer 110 form a polycide layer 111. FIG. 1 illustrates polysilicon layer 107 and metal silicide layer 110 prior to gate patterning.

FIG. 2 is a cross sectional view of semiconductor structure 100 after gate patterning and source/drain formation. Thus, polycide layer 111 is patterned to form gate electrode 121 from n+ polysilicon region 108 and metal silicide layer 110. Similarly, polycide layer 111 is patterned to form gate electrode 122 from p+ polysilicon region 109 and metal silicide layer 110. Gate electrodes 121 and 122 could be connected outside the plane of FIG. 2, thereby forming a dual-gate polycide structure 150. Source/drain regions 131-134 are formed as illustrated, thereby forming n-channel transistor 141 and p-channel transistor 142.

N+ and p+ polysilicon regions 108 and 109 have relatively high resistances. Metal silicide layer 110 advantageously provides a relatively low-resistance path for dual-gate polycide structure 150. However, metal silicide layer 110 undesirably provides a pathway through which the impurities in n+ and p+ polysilicon regions 108 and 109 can diffuse during high temperature process steps. The diffusion of n+ and p+ impurities is much faster through metal silicide layer 110 than through polysilicon regions 108 and 109. More specifically, the n-type impurity in polysilicon region 108 readily diffuses vertically into metal silicide layer 110. Similarly, the p-type impurity in polysilicon region 109 readily diffuses vertically into metal silicide layer 110. The n-type impurity diffuses through metal silicide layer 110 to p+ polysilicon region 109, thereby counter-doping region 109. Similarly, the p-type impurity diffuses through metal silicide layer 110 to n+ polysilicon region 108, thereby counter-doping region 108. This counter-doping results in unstable threshold voltages in n-channel transistor 141 and p-channel transistor 142 (with p-channel transistor 142 typically being affected the most).

In order to prevent the above-described counter-doping, a diffusion barrier consisting of titanium nitride (TiN) has been located between polysilicon layer 107 and metal silicide layer 110. The purpose of such a TiN barrier is to stop the vertical diffusion of impurities from polysilicon regions 108 and 109 to metal silicide layer 110. However, the effect of the TiN barrier varies significantly in response to various process parameters. In addition, various process issues make the use of the TiN barrier unattractive. These issues include: possible titanium contamination at the front-end of the line, the requirement for special chemicals to etch and clean the gate electrode structures, and the not well understood film adhesion characteristics of TiN/polysilicon and TiN/metal silicide film schemes.

Typically, during fabrication of dual-gate polycide structure 150, each of polysilicon regions 108 and 109 is doped by forming a corresponding photoresist mask and performing a corresponding high dosage implant operation. As a result, the upper surface of polysilicon layer 107 is quite contaminated after polysilicon regions 108 and 109 are doped, even after typical photoresist removal steps. The upper surface of polysilicon layer 107 must therefore be cleaned prior to depositing metal silicide layer 110. After cleaning, the resulting structure is transported to a chemical vapor deposition (CVD) chamber, where metal silicide layer 110 is deposited. During transport to the CVD chamber, a native oxide layer is formed on the upper surface of polysilicon layer 107 because of the exposure to the ambient atmosphere. This native oxide layer typically prevents good adhesion between metal silicide layer 110 and polysilicon layer 107. In many cases, metal silicide layer 110 will lift-off or peel either before or after polycide layer 111 is patterned. This problem is exacerbated as the polycide feature size is scaled down.

In another conventional dual-gate polycide structure, p-type impurities are implanted into metal silicide layer 110. The purpose of this implant is to prevent the p-type impurity located in p+ polysilicon region 109 from vertically diffusing into metal silicide layer 110 (because the concentration of p-type impurity is constant between metal silicide layer 110 and p+ polysilicon region 109). However, this dual-gate polycide structure requires an additional implant step. In addition, this implant does not specifically address the adhesion problem described above.

It would therefore be desirable to have a dual-gate polycide structure that overcomes the above-described deficiencies associated with conventional dual-gate polycide structures.

### SUMMARY

Accordingly, the present invention provides a dual-gate polycide structure that includes a first polysilicon layer having a p+ region and an n+ region. The p+ polysilicon region is formed by a first mask and implant process, and the n+ polysilicon region is formed by a second mask and implant process. The mask and implant processes are performed such that the p+ polysilicon region and the n+ polysilicon region are continuous in the first polysilicon layer. In one embodiment, the p+ polysilicon region overlies the channel region of a p-channel transistor, and the n+ polysilicon region overlies the channel region of an n-channel transistor.

The upper surface of the first polysilicon layer is cleaned, and then a second polysilicon layer is formed directly on the upper surface of the first polysilicon layer. Because both the first polysilicon layer and the second polysilicon layer are made of polysilicon, the second polysilicon layer has good adhesion with the first polysilicon layer. The second polysilicon layer can be deposited with good adhesion even if the upper surface of the first polysilicon layer is not completely free of native oxide.

A metal silicide layer is then deposited on the second polysilicon layer. The second polysilicon layer and the metal silicide layer are deposited in the same equipment, but different chambers, without breaking vacuum (i.e., in situ). As a result, the upper surface of the second polysilicon layer is clean (i.e., without a native oxide), thereby providing good adhesion between the metal silicide layer and the second polysilicon layer. Consequently, peeling between the metal silicide layer and the second polysilicon layer is eliminated.

The second polysilicon layer can be formed by depositing either undoped polysilicon or polysilicon doped with nitrogen. The second polysilicon layer provides an additional distance for impurities to diffuse from the first polysilicon layer to the metal silicide layer. Nitrogen doping of the second polysilicon layer also reduces the diffusion of impurities from the first polysilicon layer to the metal silicide layer. As a result, the second polysilicon layer inhibits the vertical migration of impurities from the p+ polysilicon region and the n+ polysilicon region to the overlying metal silicide layer. Consequently, counter-doping is advantageously minimized.

The present invention will be more fully understood in view of the following description and drawings.

### BRIEF DESCRIPTION OF THE DRAWINGS

FIG. 1 is a cross sectional diagram of a conventional semiconductor structure having a polycide layer prior to gate patterning;

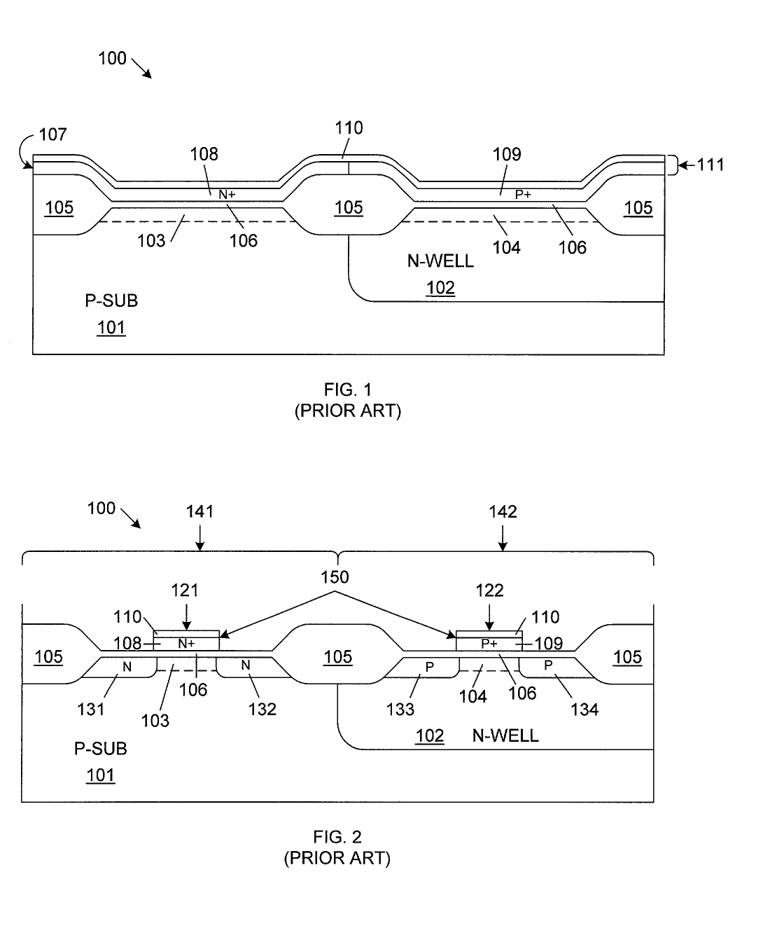

FIG. 2 is a cross sectional diagram of the semiconductor structure of FIG. 1 after gate patterning and source/drain formation;

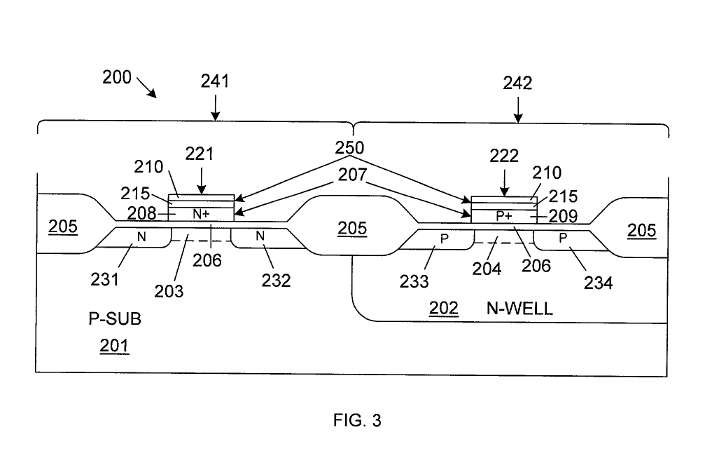

FIG. 3 is a cross sectional diagram of a dual-gate semiconductor structure in accordance with one embodiment of the present invention; and

FIGS. 4-9 are cross sectional diagrams illustrating the fabrication of the dual-gate semiconductor structure of FIG. 3 in accordance with one embodiment of the present invention.

### DETAILED DESCRIPTION

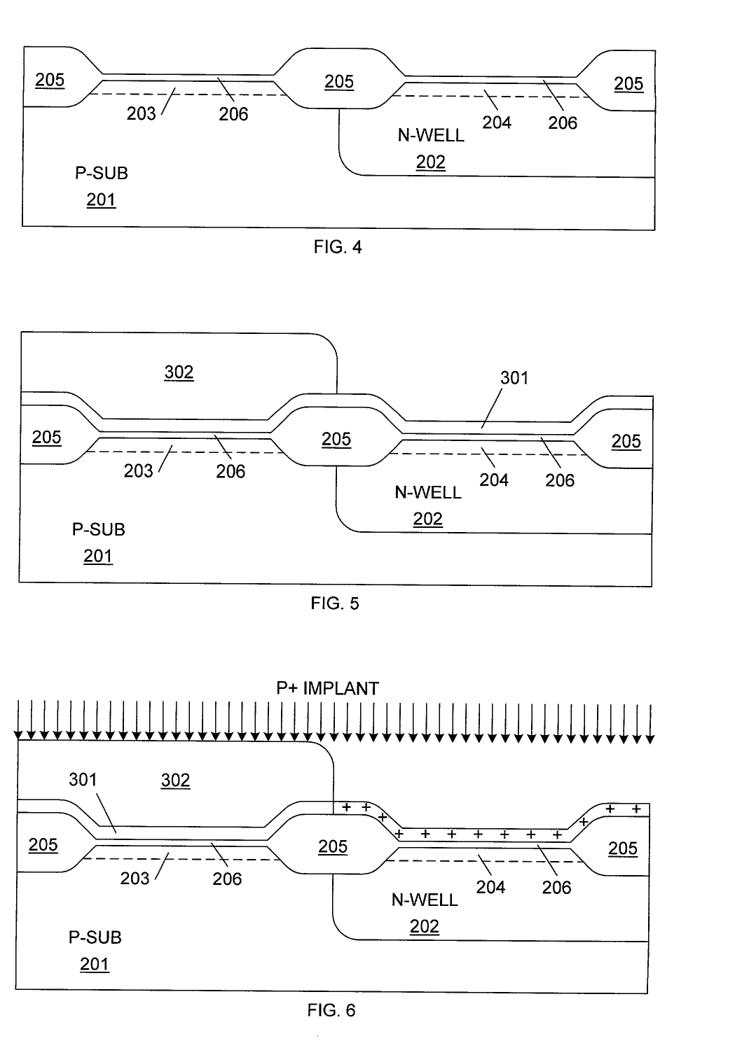

FIG. 3 is a cross sectional diagram of a dual-gate semiconductor structure 200 in accordance with one embodiment of the present invention. Dual-gate semiconductor structure 200 includes p-type monocrystalline silicon substrate 201, n-well 202, p-type channel region 203, n-type channel region 204, field oxide 205, gate oxide 206, a first polysilicon layer 207, a second polysilicon layer 215 and metal silicide layer 210. First polysilicon layer 207 includes n+ type polysilicon region 208 and p+ type polysilicon region 209. Second polysilicon layer 215 is either undoped, or doped with an inert element, such as nitrogen. In the described embodiment, n+ polysilicon region 208, polysilicon layer 215 and metal silicide layer 210 form the gate electrode 221 for an n-channel transistor 241. Similarly, p+ polysilicon region 209, polysilicon layer 210 and metal silicide layer 210 form the gate electrode 222 of a p-channel transistor 242. In the described embodiment, first polysilicon layer 207, second polysilicon layer 215, and metal silicide layer 210 are connected outside of the plane of FIG. 3, thereby forming a dual-gate polycide structure 250. (In other embodiments, first polysilicon layer 207, second polysilicon layer 215 and metal silicide layer 210 are not connected outside of the plane of FIG. 3.) N-type regions 231 and 232, which are formed in p-type substrate 201, form the source/drain regions of n-channel transistor 241. P-type regions 233 and 234, which are formed in n-well 202, form the source/drain regions of p-channel transistor 242.

Second polysilicon layer 215 provides several advantages to dual-gate polycide structure 250. First, polysilicon layer 215 provides an additional layer separating n+ polysilicon region 108 and p+ polysilicon region 209 from the overlying metal silicide layer 210, thereby inhibiting the diffusion of impurities between these layers. When polysilicon layer 215 is doped with an inert element, such as nitrogen, the diffusion of impurities between these layers is further inhibited. By inhibiting the diffusion of impurities from n+ polysilicon region 108 and p+ polysilicon region 209 to the overlying metal silicide layer 210, counter-doping of these regions 208-209 is advantageously minimized during the fabrication of dual gate polycide structure 250.

In addition, as described in more detail below, second polysilicon layer 215 provides for improved adhesion between the various layers of dual-gate polycide structure 250, thereby advantageously eliminating peeling or lift off of metal silicide layer 210.

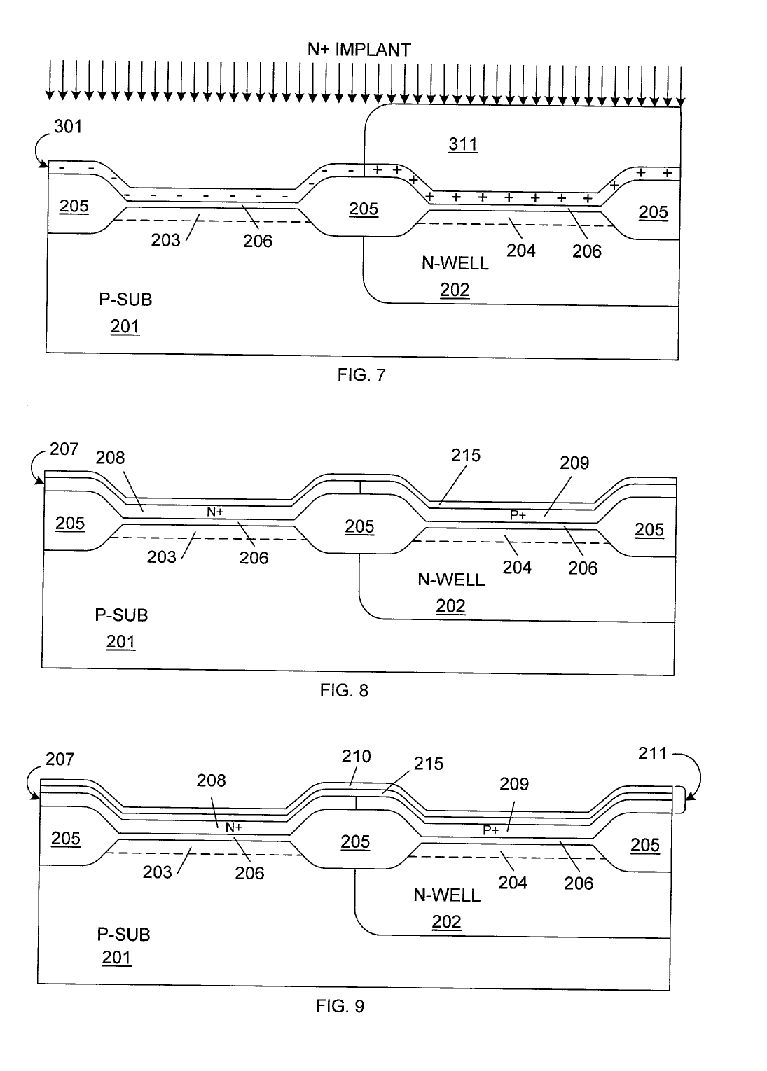

FIGS. 4-9 are cross sectional views illustrating semiconductor structure 200 during various stages of processing. Semiconductor structure 200 is fabricated as follows. N-well 202 is formed in p-type substrate 201 using conventional processing methods. For example, n-well 202 can be formed by masking an area that blocks a region of p-type substrate 201, and then implanting an n-type impurity, such as arsenic. A subsequent heating step anneals the n-type impurity, thereby forming n-well 202. Other conventional methods of forming n-well 202 can also be used.

Field oxide 205 is then formed by a conventional method, such as LOCOS. In the described embodiment, field oxide 205 is silicon oxide having a thickness of about 3000 to 4000 Angstroms. Field oxide 205 can have other thicknesses in other embodiments. Channel regions 203 and 204 can then be doped to provide the desired threshold voltages for the resulting transistors 241-242. This doping is performed using a conventional processing method (e.g., ion implantation). Gate oxide 206 is then formed by a conventional method, such as thermal oxidation. In the described embodiment, gate oxide 206 has a thickness of about 25 to 100 Angstroms, depending on the particular process. The gate oxide thickness can be thicker or thinner in other embodiments. The resulting structure is illustrated in FIG. 4.

As illustrated in FIG. 5, an undoped layer of polysilicon 301 is then deposited over the upper surface of the structure of FIG. 3. In the described embodiment, undoped polysilicon layer 301 is deposited to a thickness of about 2000 Angstroms using a conventional processing method. Undoped polysilicon layer 301 can be deposited to other thicknesses in other embodiments. A layer of photoresist is then deposited over undoped polysilicon layer 301. This photoresist layer is exposed through a reticle that defines the location of p+ polysilicon region 209. The exposed photoresist layer is then developed, thereby forming p+ polysilicon region mask 302. As illustrated in FIG. 5, p+ polysilicon region mask 302 has an opening where p+ polysilicon region 209 is to be formed.

As illustrated in FIG. 6, a p+ ion implant is performed through p+ polysilicon region mask 302, thereby placing p+ ions in the exposed portion of polysilicon layer 301. In the described embodiment, the p+ ion implant is performed by implanting boron ions at an energy of 10 to 20 keV and a dosage of 2 to 8 E15 cm−2.

P+ polysilicon region mask 302 is then stripped, and n+ polysilicon region mask 311 is formed as illustrated in FIG. 7. N+ polysilicon region mask 311 is formed in the same manner as p+ polysilicon region mask 302. As illustrated in FIG. 7, n+ polysilicon region mask 311 has an opening where n+ polysilicon region 208 is to be formed. An n+ ion implant is performed through n+ polysilicon region mask 311, thereby placing n+ ions in the exposed portion of polysilicon layer 301. In the described embodiment, the n+ ion implant is performed by implanting arsenic ions at an energy of 50 to 70 keV and a dosage of 2 to 8 E15 cm−2.

N+ polysilicon region mask 311 is then stripped, and the upper surface of polysilicon layer 301 is cleaned. These steps are performed by ashing in an O₂ plasma, thereby burning off photoresist mask 311. A chemical clean is then performed using sulfuric acid (H₂SO₄), HF and Ammonia-based (NH₄OH/H₂O₂) chemicals. An anneal step is then performed, thereby activating the impurities implanted in polysilicon layer 301, and forming n+ polysilicon region 208 and p+ polysilicon region 209 of polysilicon layer 207. In the described embodiment, the anneal step is a rapid thermal anneal (RTA) performed for 10 to 30 seconds at 900 to 1100° C.

Second polysilicon layer 215 is then deposited on the cleaned upper surface of polysilicon layer 207, as illustrated in FIG. 8. Polysilicon layer 215 is formed by chemical vapor deposition (CVD) of polycrystalline silicon in a vacuum chamber. In one embodiment, polysilicon layer 215 is undoped polysilicon. In another embodiment, polysilicon layer is doped with an inert element, such as nitrogen. In the described embodiment, polysilicon layer 215 has a thickness in the range of 100-300 Angstroms. However, other thicknesses are possible and are considered to fall within the scope of the present invention. In one embodiment, the thickness of second polysilicon layer 215 is an order of magnitude less than the thickness of first polysilicon layer 207. Polysilicon layer 215 exhibits good adhesion to underlying polysilicon layer 207 regardless of whether polysilicon layer 207 is well cleaned or whether a slight native oxide is present on the upper surface of polysilicon layer 207. Native oxide is commonly formed on the upper surface of polysilicon layer 207 as the wafer is being transported in an ambient environment prior to being loaded into the vacuum chamber.

In an alternate embodiment, n+ polysilicon region mask 311 is stripped and cleaned and the resulting structure is loaded into a vacuum chamber. The upper surface of the resulting structure is then cleaned additionally by performing RTA in a hydrogen (H₂) atmosphere. In one embodiment, this RTA is performed at a temperature of 850 to 950° C. for 30 to 60 seconds. In addition to cleaning the upper surface of polysilicon layer 301, this step also activates the impurities implanted in polysilicon layer 301, thereby forming n+ polysilicon region 208 and p+ polysilicon region 209 in doped polysilicon layer 207. Combining the cleaning and annealing steps in this manner advantageously reduces the number of process steps required to form the resulting dual-gate polycide structure. Second polysilicon layer 215 is then deposited over the doped polysilicon layer 207 in the same equipment, without breaking the established vacuum.

After polysilicon layer 215 has been deposited, metal silicide layer 210 is deposited as illustrated in FIG. 9. In accordance with the present invention, metal silicide layer 210 is deposited in situ. That is, metal silicide layer 210 is deposited by CVD in the same platform (or system), but in a different chamber that polysilicon layer 215 was deposited. The vacuum is not broken between the deposition of polysilicon layer 215 and the deposition of metal silicide layer 210. As a result, no oxide is present at the upper surface of polysilicon layer 215 when metal silicide layer 210 is deposited. By forming metal silicide layer 210 on the clean upper surface of polysilicon layer 215, lift-off and peeling problems are substantially eliminated. In the described embodiment, metal silicide layer 210 is tungsten silicide (WSiₓ) deposited to a thickness in the range of 1000 to 2000 Angstroms. However, in other embodiments, other types of metal silicide can be deposited. Similarly, metal silicide layer 210 can have other thicknesses in other embodiments.

Doped polysilicon layer 207, polysilicon layer 215 and metal silicide layer 210 are subsequently patterned to form dual-gate polycide structure 250, which includes gate electrodes 221 and 222 (FIG. 3). A masked n-type implant is then performed to place n-type impurities into source/drain regions 231-232. Similarly, masked p-type implant is performed to place p-type impurities into source/drain regions 233-234. An anneal is subsequently performed to activate metal silicide layer 210 with underlying polysilicon layers 207 and 215 to reduce the film resistance. This anneal also activates the impurities implanted in source/drain regions 231-234. In one embodiment, this anneal is an RTA performed by heating to a temperature of 800 to 1000° C. for 10 to 30 seconds. During this anneal, polysilicon layer 215 delays or retards the vertical diffusion of impurities between doped polysilicon regions 208-209 and metal silicide layer 210. As a result, counter-doping of polysilicon regions 208 and 209 (through metal silicide layer 210) is minimized.

Note that the characteristics of n-channel transistor 241 are mainly determined by the joined interfacial region between gate oxide 206 and overlying n+ polysilicon region 208. Similarly, the characteristics of p-channel transistor 242 are mainly determined by the interfacial region between gate oxide 206 and overlying p+ polysilicon region 209. Because second polysilicon layer 215 is located relatively far from these junctions, the insertion of second polysilicon layer 215 does not significantly affect the characteristics of transistors 241 and 242.

Also note that the electrical conductivity of dual-gate polycide structure 211 is primarily provided by metal silicide layer 210. As a result, the insertion of second polysilicon layer 215 does not significantly affect the gate conductivity of transistors 241 and 242.

Although the present invention has been described in connection with several embodiments, it is understood that this invention is not limited to the embodiments disclosed, but is capable of various modifications which would be apparent to one of ordinary skill in the art. Thus, the invention is limited only by the following claims.

1. A method of fabricating a dual-gate structure, the method comprising the steps of:
depositing a first polysilicon layer over a semiconductor substrate;
doping a first region of the first polysilicon layer with an impurity having a first conductivity type;
doping a second region of the first polysilicon layer with an impurity having a second conductivity type, opposite the first conductivity type;
depositing a second polysilicon layer on the first polysilicon layer; and
depositing a metal silicide layer on the second polysilicon layer.

2. The method of claim 1, wherein the steps of depositing the second polysilicon layer and the metal silicide layer are performed in situ.

3. The method of claim 2, further comprising the step of cleaning and annealing the first polysilicon layer in situ.

4. The method of claim 1, wherein the second polysilicon layer is undoped.

5. The method of claim 1, wherein the second polysilicon layer is doped with an inert element.

6. The method of claim 5, wherein the inert element is nitrogen.

7. The method of claim 3, wherein the step of cleaning and annealing includes:
loading the structure including the semiconductor substrate and the first polysilicon layer having the doped first and second regions into a vacuum chamber; then
establishing a vacuum in the vacuum chamber; and then
performing a rapid thermal anneal in a hydrogen (H₂) atmosphere.

8. The method of claim 7, wherein the rapid thermal anneal is performed at a temperature of 850 to 950° C. for 30 to 60 seconds.

9. The method of claim 1, wherein the second polysilicon layer is deposited by chemical-vapor deposition (CVD).

10. The method of claim 9, wherein the metal silicide layer is deposited by CVD.
